(19) United States
(12) Patent Application Publication
(10) Pub. No.: US 2024/0291566 A1
(43) Pub. Date: Aug. 29, 2024

(54) PHOTONIC INTEGRATED CIRCUIT INCLUDING SEMICONDUCTOR OPTICAL AMPLIFIERS

(71) Applicant: Infinera Corporation, San Jose, CA (US)

(72) Inventors: Vikrant Lal, Sunnyvale, CA (US); Peter Evans, Terrell, TX (US); David Welch, Atherton, CA (US); Mehrdad Ziari, Pleasanton, CA (US); Scott Corzine, Sunnyvale, CA (US); Thomas Frost, San Jose, CA (US)

(73) Assignee: Infinera Corporation, San Jose, CA (US)

(21) Appl. No.: 18/400,565

(22) Filed: Dec. 29, 2023

Related U.S. Application Data
(60) Provisional application No. 63/541,651, filed on Sep. 29, 2023.
(60) Provisional application No. 63/446,490, filed on Feb. 17, 2023.

(51) Int. Cl. H04B 10/291; H04B 10/40; H04B 10/50; H04B 10/548

(52) U.S. Cl. CPC H04B 10/2914; H04B 10/40; H04B 10/505; H04B 10/548

(57) ABSTRACT

Consistent with the present disclosure, a transceiver is implemented as a photonic integrated circuit (PIC) that includes a transmitter and a receiver. A laser is also provided that provides light to a splitter, which supplies a first portion of the light to the transmitter and a second power of the light to the receiver. Semiconductor optical amplifiers (SOAs) are provided at one or more locations on the PIC. In one example, at least one SOA is provided in the transmitter so that the transmitted optical signal has a desired power, and at least another SOA is provided in the receiver so that the local oscillator signal has a desired power. In a further example, an SOA is provided in the receiver to boost the power of the received optical signal. Preferably, the transceiver, including the SOAs, is monolithically integrated on a substrate, such as a substrate including indium phosphide (InP). Moreover, the SOA can be readily controlled via a low voltage current source consuming minimal electrical power.

### BACKGROUND

The present patent application hereby claims priority to the provisional patent application identified by U.S. Ser. No. 63/446,490, filed on Feb. 17, 2023, the entire content of which is hereby incorporated by reference.

Optical transceivers are known which include a transmitter portion and a receiver portion. The transmitter portion outputs a modulated first optical signal that typically carries information to a first optical path, including, for example, an optical fiber, and a receiver portion that typically receives second information-carrying optical signals from a second optical path, which also includes, for example, an optical fiber. The transmitter portion may include a modulator that modulates light output from an optical source, such as a laser, to thereby provide the modulated optical signal. The receiver portion, on the other hand, may include photodiodes that detect the incoming signal in intensity-modulated, direct detection systems. If a coherent receiver is deployed, the receiver portion may include optical hybrids that mix local oscillator light with an incoming optical signal, and photodiodes to detect the outputs of the optical hybrids.

In order to reduce electrical power supplied to the transceiver or, in some instances, to assure that the transmitted optical signal wavelength is close to the received optical signal wavelength, the transmitter and receiver portions may “share” a common laser. That is, the output of the laser is provided to a power splitter, which provides a first portion of the laser output to the transmitter and the modulator, and a second portion of the laser output to the optical hybrids as a local oscillator signal. Moreover, in order to reduce the size of the transceiver to be compatible with certain module form factors, the various components of the transceiver, such as the laser, modulators, optical hybrids, and photodiodes, are integrated on a common substrate as a photonic integrated circuit.

The optical characteristics of the transmitted optical signal and the optical characteristics of the local oscillator signal are often not the same. For example, the transmit optical power may have a particular optimal value that provides the best transmit optical signal-to-noise-ratio and reduced impairments. Such optimal transmit power may be different than a desired local oscillator power, which is optimized to maximize the sensitivity or minimize the required signal to noise ratio of the coherent receiver.

Accordingly, transceivers having shared lasers are often designed whereby tradeoffs are made between optimal transmit and local oscillator power, such that neither is optimal.

### SUMMARY

Consistent with an aspect of the present disclosure, a photonic integrated circuit is provided that comprises a substrate and a laser provided on the substrate. The photonic integrated circuit includes a transmitter portion that receives a first portion of an optical signal output from the laser, wherein the transmitter portion being provided on the substrate. A first semiconductor optical amplifier is provided in the transmitter portion, such that an output of the transmitter portion is greater than an output of the transmitter portion in an absence of the first semiconductor optical amplifier. A receiver portion is also provided on the substrate, the receiver portion receiving a second portion of the optical signal output from the laser as a local oscillator signal. In addition, the receiver portion includes a photodiode circuit. A second semiconductor optical amplifier or variable optical attenuator is provided in the receiver portion to adjust a power of an optical input to the photodiode circuit, wherein the transmitter portion, the laser, the first and second optical amplifiers, and the receiver portion are monolithically integrated on the substrate.

It is to be understood that both the foregoing general description and the following detailed description are exemplary and explanatory only and are not restrictive of the invention, as claimed.

The accompanying drawings, which are incorporated in and constitute a part of this specification, illustrate several embodiments and together with the description, serve to explain the principles of the invention.

### BRIEF DESCRIPTION OF THE DRAWINGS

FIG. 1 is a block diagram of an example of a transceiver consistent with an aspect of the present disclosure;

FIG. 2 illustrates a block diagram of an example of a transceiver consistent with a further aspect of the present disclosure;

FIG. 3 illustrates a transmitter consistent with an additional aspect of the present disclosure;

FIGS. 4 and 5 illustrate examples of receivers consistent with aspects of the present disclosure;

FIGS. 6-8 and 9a-9d show examples of semiconductor optical amplifiers consistent with additional aspects of the present disclosure;

FIGS. 10a and 10b show an examples of a plot of signal-to-noise-ratio vs. input optical signal power for different SOA gains for amplifying the local oscillator signal;

FIGS. 11 and 12 show further examples of transceivers consistent with the present disclosure; and

FIG. 13 shows a further example of a receiver consistent with the present disclosure.

### DESCRIPTION OF THE EMBODIMENTS

Consistent with the present disclosure, a transceiver is implemented as a photonic integrated circuit (PIC) that includes a transmitter and a receiver. A laser is also provided that, in one example, provides light to a splitter, which supplies a first portion of the light to the transmitter and a second power of the light to the receiver. Semiconductor optical amplifiers (SOAs) are provided at one or more locations on the PIC. In one example, at least one SOA is provided in the transmitter so that the transmitted optical signal has a desired power, and at least another SOA is provided in the receiver so that the local oscillator signal has a desired power. In a further example, an SOA is provided in the receiver to boost the power of the received optical signal. Preferably, the transceiver, including the SOAs, is monolithically integrated on a substrate, such as a substrate including indium phosphide (InP). In another example, the substrate may include a layer of InP provided on silicon or silicon dioxide (SiO₂). As used herein, a “substrate” is a material upon which one or more layers are provided or grown on it. Moreover, the SOA can be readily controlled via a low voltage current source or other control circuitry.

In another example, two or more lasers are provided on the PIC. If two lasers are provided, the first laser supplies light to modulator circuits, which output modulated optical signals for transmission in an optical fiber. In addition, the second laser supplies a local oscillator signal to optical hybrid circuits, which may also be integrated in the PIC.

The addition of an optical amplifier in the local oscillator optical path provides for higher power and improved sensitivity as well as the ability to control and optimize performance of the receiver. Further, the ability to amplify receiver local oscillator power enables increasing the modulated optical signal power to thereby improve performance.

Receiver (Rx) sensitivity scales with the optical power of the “local oscillator”. As noted above, the partitioning of laser power between the transmitter and receiver may result in a tradeoff of transmit parameters, such as transmitted optical signal power and transmit optical signal-to-noise-ratio (TOSNR) versus receiver sensitivity. Consistent with a further aspect of the present disclosure, amplification of laser (local oscillator) power on the receiver path enables optimized performance beyond the power limits of the laser.

As noted above, the SOA may be readily controlled. The ability to dynamically control the local oscillator power provides for enhanced control functions and optimizing performance relative to a received signal by adjusting the local oscillator power.

In the case of the Tx side, amplification before, within and after the modulator section can optimize optical SNR (OSNR) and transmitter output power. The distribution of amplification stages can provide for sufficient gain to overcome various noise limits, boost power, and provide control functions such as dimming, shuttering and power balancing between polarizations and/or between in-phase and quadrature components of the optical signal.

It is noted that a silicon photonics (SiPh) implementation often requires an optical fiber amplifier at the transmitter. The signal-to-noise ratio (SNR) of an output of a SiPh transmitter without amplification is unfavorable and a tunable optical filter is required to remove the amplifier noise to deliver the required transmitted optical SNR (TOSNR). Consistent with the present disclosure, however, amplification may be distributed on the PIC, for example, by providing SOAs at various locations on the substrate, which includes indium phosphide. As a result, higher optical power is maintained throughout the circuit so that higher signal to noise ratio is preserved, and therefore a spectral filter function is not essential at the transmitter output. Therefore, power is boosted throughout the circuit to overcome the circuit losses early in the power train, e.g., at the output of the laser or prior to, in the modulator, or at the output of the modulator.

Consistent with a further aspect of the present disclosure, SOAs provided in the local oscillator path can be common between the two polarizations or independent for each polarization. One or more SOAs may be used to control the LO signal level and move the receiver sensitivity curve, often referred to as a “bathtub curve,” and ensure adequate received power and optical signal to noise ratio. In addition, independent SOAs, one for each polarization, may compensate for any polarization imbalance resulting from loss variations in the circuits. The SOA gains can be controlled: by a low voltage current source, dynamically in a control loop, and/or in response to the system requirements.

Moreover, inclusion of SOAs in the Rx signal path, for example, can be used to amplify a weak incoming or input signal. However, there may be trade-offs on overall noise depending on the amplifier gain, noise figure and background amplified stimulated emission (ASE).

The orientation of the SOAs can be optimized so as not to direct any stray light at photodetectors or other light sensitive elements in the transmitter or receiver portions of the PIC, or externally into sensitive optics within a module housing the PIC.

In one example, the SOA on the LO path amplifies a low noise laser light of moderate power (>0 dBm) and will not compromise the lower power input signal by amplification noise and amplified spontaneous emission noise of the SOA.

In addition, SOAs consistent with the present disclosure can function or operate as a switch to turn the optical path(s) off for shuttering or configurability. To shutter or greatly attenuate light in an SOA path, the SOA may be grounded or reverse biased to absorb light.

The SOAs can be multi-sectioned to optimize output power, gain, gain linearity, bandwidth, overall power consumption, or noise. As a result, linearity for coherent applications may be preserved and the optical bandwidth may be extended. Further, SOAs consistent with the present disclosure may include different epitaxial layers and gain centers at different PIC locations as the C and L band are extended or combined.

In addition, a coherent scheme to increase and control the output power in different parts of the circuit can be used through the use of multiple SOAs.

Consistent with an additional aspect of the present disclosure, one or more variable optical attenuators may be provided in addition to or instead of the SOAs described above, to adjust the transmitted optical signal power, local oscillator power, and/or received optical signal power to a desired level. In one example, the variable optical attenuator may be an SOA, as described above, that is biased to be absorptive as opposed to providing gain.

Reference will now be made in detail to the present exemplary embodiments of the present disclosure, which are illustrated in the accompanying drawings. Wherever possible, the same reference numbers will be used throughout the drawings to refer to the same or like parts.

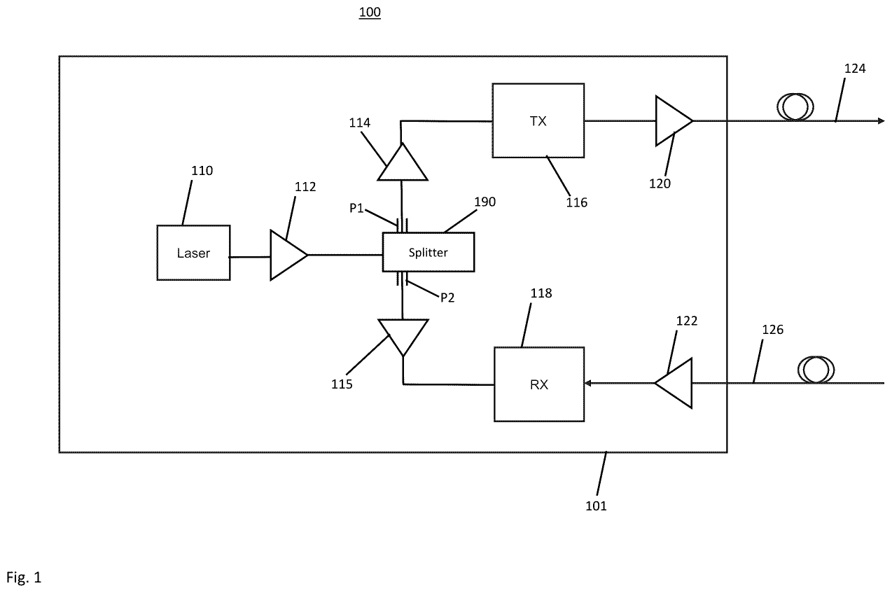

FIG. 1 shows an example of a transceiver photonic integrated circuit (PIC) 100 consistent the present disclosure. PIC 100 includes, for example, a substrate 101. A laser 110 is provided on the substrate. In one example, SOA 112 is optionally provided on the substrate and is operable to receive light output from laser 110. SOA 112 provides an optical output to splitter 190, which has first (P1) and second (P2) ports. Port P1 feeds a first portion of the optical signal or light output from laser 110 to SOA 114, and port P2 feeds a second portion of the optical signal or light output from laser 110 to SOA 115. An output of SOA 114 is provided to transmitter or transmitter portion 116, and an output of SOA 115 is provided as a local oscillator signal to receiver or receiver portion 118. SOA 120 may be provided to amplify the output of transmitter 116, e.g., a modulated optical signal, which is supplied to an optical communication path including fiber 124, and SOA 122 may be provided to amplify an input modulated optical signal transmitted on fiber 126 and supply, for example, an amplified input optical signal to receiver 118.

In one example, the modulated optical signal output from transmitter 116 is a polarization multiplexed optical signal including both transverse electric (TE) and transverse magnetic (TM) polarization components. Further, the input modulated optical signal carried by fiber 126 similarly has TE and TM components, for example. Accordingly, both SOAs 120 and 122 are preferably polarization insensitive.

In addition, it is noted that the optical power associated with the modulated optical signal output from transmitter 116 onto fiber 124 may be greater than the power associated with the received modulated optical signal carried by fiber 126. Accordingly, SOA 122 may more efficiently provide gain by operating in the linear regime. However, it is further noted that the regime in which each SOA described herein operates is typically based on the input signal power level, SOA length, and bias current, such that lower input signal power levels will more likely cause the SOA to operate in the linear regime, whether output from the transmitter or received from optical fiber 126, for example. Higher input power levels and bias current, regardless of whether the SOA is receiving signals to be transmitted or received signals intended for the receiver, may cause the SOA to operate in saturation or closer to saturation.

Further, the laser signal power supplied to transmitter 116 may be the same or different than the power supplied to receiver 118. Different power levels may be realized by providing splitter 190 with a desired splitting ratio (e.g., the power level output from port P1 may be 90% of the output power from laser 110 and the output from port P2 may be 10% of such power). Alternatively, the gain and output powers of SOAs 114 and 115 may be adjusted to provide the desired power ratio between transmitter 116 and receiver 118. Further, in another example, the desired power ratio may be realized with a combination of a given splitter ratio and gains/output power levels associated with SOA 114 and 115.

Laser 110 is, for example, a semiconductor laser. In a further example, laser 110 may be a distributed Bragg reflector (DBR) laser, a sampled grating DBR laser, a micro-ring laser, or a distributed feedback (DFB) laser. Other lasers may also be employed that may, for example, be integrated onto substrate 101.

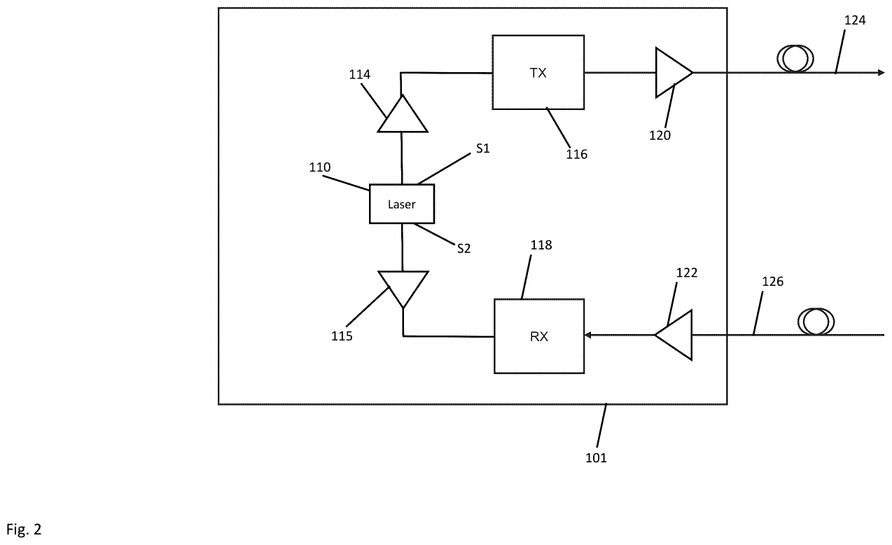

FIG. 2 shows an example of transceiver PIC 100 similar to that shown in FIG. 1. In FIG. 2, however, splitter 190 is omitted. Instead, light is output from side S1 of laser 110 to SOA 114 and light output from side S2 of is output to SOA 115. The operation of transceiver PIC 100 is otherwise similar to that described above in regard to FIG. 1.

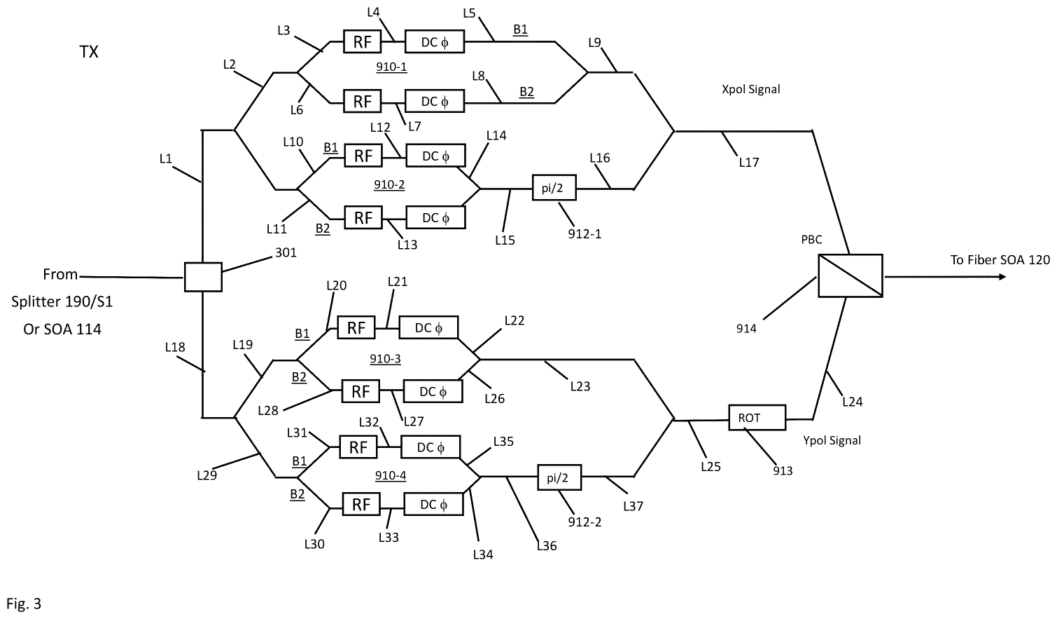

FIG. 3 modulators 910-1 to 910-4 of transmitter 116 are shown in greater detail. Each modulator 910-1 to 910-4 may be, for example, a Mach-Zehnder modulator (MZM) that modulates the phase and/or amplitude of the light output from SOA 114, or, if SOA 114 is absent, a first portion of the laser light supplied from port P1. As further shown in FIG. 3, light output from port P1 or from laser side S1, is split by splitter 301, such that a first portion of the light is supplied to a first MZM pairing, including MZMs 910-1 and 910-2 (both also being sub-MZMs), and a second portion of the light output from a second output of splitter 301 is supplied to a second MZM pairing, including MZMs 910-3 and 910-4. The first portion of the light is split further into third and fourth portions, such that the third portion is modulated by MZM 910-1 to provide an in-phase (I) component of a modulated optical signal X, and the fourth portion is modulated by MZM 910-2 and fed to phase shifter 912-1 to shift the phase of such light by 90 degrees in order to provide a quadrature (Q) component of the modulated optical signal X. Similarly, the second portion of the light is further split into fifth and sixth portions, such that the fifth portion is modulated by MZM 910-3 to provide an I component of a modulated optical signal Y, and the sixth portion is modulated by MZM 910-4 and fed to phase shifter 912-2 to shift the phase of such light by 90 degrees to provide a Q component of the modulated optical signal Y. The Y polarization components are TE polarization in the modulators and converted to TM polarization in the 913 ROT element.

As further shown in FIG. 3, each MZM has first and second branches, B1 and B2, and each branch has an RF electrode and a DC electrode, which, in one example, adjusts the phase of the signal propagating in each branch. The RF electrode receives a DC reverse bias and high frequency electrical signals indicative of data carried by the modulated optical signal output from the transmitter. Such signals have frequencies in a range of 5 GHz to 300 GHz. Each of branches B1 and B2 of the MZMs 910 also has a DC electrode receiving a reference or bias voltage or a low frequency signal which, in one example, does not exceed 5 MHz. Each of the RF electrodes and the DC phase electrodes are connected to a modulator driver circuit that outputs the high frequency and low frequency signals, both of which, in a further example, include a voltage and/or a current.

As used herein, a “modulator” may refer to individual modulators, such as MZMs 910-1 to 910-4, noted above, as well as such MZMs taken collectively.

A number of locations (L1 to L37) are labeled in FIG. 3. Consistent with an aspect of the present disclosure, an SOA, similar to one of those described above, may be provided at one or more of such locations. The location or locations may be based on the locations of control circuitry for controlling the biasing the RF and DC electrodes noted above, as well as the SOAs themselves (by way of current digital-to-analog converters (IDACs) and voltage DACs (VDACs), as well as the power dissipation associated with the SOAs, and the transmit OSNR.

In one example, light output from branches B1 and B2 of MZM 910-1 may experience high loss when modulated and combined at the output of MZM 910-1. Accordingly, one or more SOAs may be provided at a respective one of locations L1, L2-L5, and L6-L8 to maintain adequate optical power and TOSNR. That is, an SOA may be provided at one or more of these locations, which are upstream from the MZM 910-1 output, where the signals carried by branches B1 and B2 of MZM 910-1 combine. In a further example, the SOA may be provided at one or more of locations L4 and L5, after the RF electrode but before the optical branch signals are combined at L9. In this way, the RF electrode modulator element is not loaded with as much amplified light, which may otherwise increase noise, laser linewidth, and power dissipation more. SOAs may also be provided in corresponding locations in each of MZMs 910-2 to 910-4.

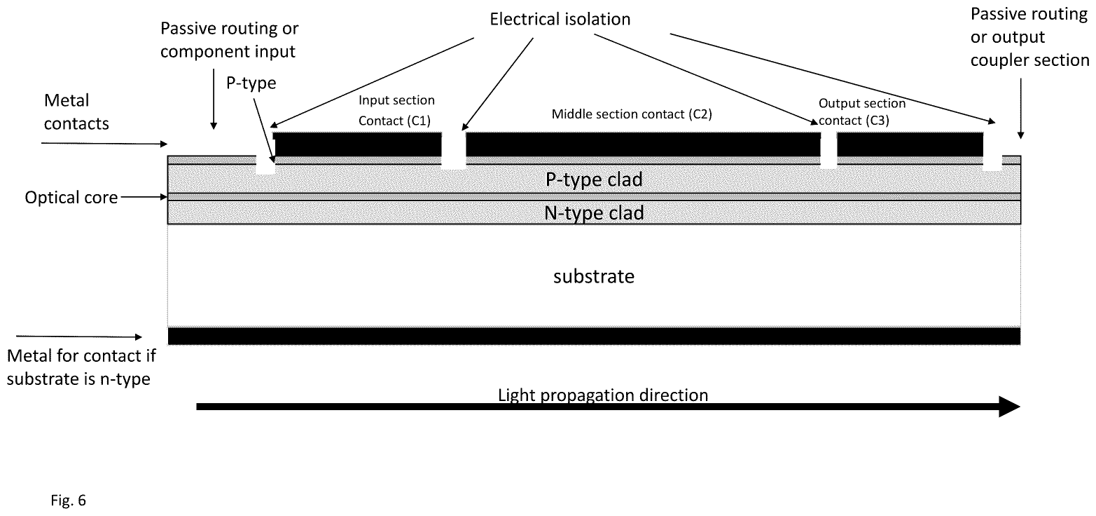

In addition, SOAs may be provided in one or more locations in each of branches B1 and B2 of MZMs 910-1 to 910-2 in order to balance the optical power of the optical signals propagating in each branch so that, in one example, the optical power in each branch is the same or substantially the same or comply with layout constraints. In addition, SOAs may have multiple sections that may each be controlled separately or with a common electrode, as discussed below with reference to FIGS. 6-8 and 9a-9d. When input power to SOAs is sufficiently high, the OSNR is not degraded by the noise figure of the SOA (typically around 6 to 7 dB for semiconductor SOAs), but when the input power to SOAs is not sufficiently high, the OSNR is degraded by up to the noise figure of the SOA.

In another example, an SOA may be provided before the RF electrode in each of branches B1 and B2. As noted above, SOAs may be provided after the RF electrode instead or may be electrically driven in parallel to maximize TOSNR and control simplicity. After the modulator, optical power may be amplified by placing SOAs at one or more locations L15, L16, L17, L23, L24, L25, L36, and L37, although the SOA noise figure will typically degrade the OSNR at these points, when the signal power into these SOAs is not high enough. The DC phase adjustor electrode can be located at any location along either branch B1 or B2 in each of MZMs 910-1 to 910-2. But extra electrical noise filtering and phase tracking may be required for putting SOAs inside of MZMs 910-1 to 910-4 instead of outside such MZMs.

Preferably, the number of SOAs and the placement of such SOAs is determined such that OSNR is maximized by keeping optical power high enough without costing too much power dissipation (Pdiss), active/passive transition losses, PIC real estate, or control difficulty.

The optical outputs of MZMs 910-1 and 910-2 are combined to provide a modulated optical signal X (“X pol”) including I and Q components and are fed to a polarization beam combiner (PBC) 914. In addition, the outputs of MZMs 910-3 and 910-4 are combined to provide an optical signal that is fed to polarization rotator 913, further provided in block 101, that rotates the polarization of modulated optical signal Y to the TM polarization. The modulated optical signal Y (“Y pol”) also is provided to PBC 914, which combines the X and Y polarized modulated optical signals to provide a polarization multiplexed (“dual-pol”) modulated optical signal onto optical fiber 124, by way of optional SOA 120. It is noted that the X pol and Y pol signals may alternatively referred to as transverse electric (TE) signals and transverse magnetic (TM) signals, in particular, the if such signals are orthogonal to each other. The present disclosure, however, is not limited to transmission and reception of optical signals having polarizations that are orthogonal to one another. Optical signals having non-orthogonal, polarizations are also contemplated herein.

In a further example, one or more SOAs may be provided at selected locations along an X polarization path, which includes an optical path including a first output of splitter 301, MZMs 910-1 and 910-2 and a first input to PBC 914. Also, one or more SOAs may be provided at selected locations along a Y polarization path, which includes an optical path including a second output of splitter 301, MZMs 910-3 and 910-4, rotator 913 and a second input to PBC 914. The number of SOAs and the locations (L1 to L37) where such SOAs may be provided in the various paths may be selected such that the optical power of signal propagating in such paths is balanced such that the optical power in each of modulated signal paths is the same or substantially the same, in one example.

In a further example, SOAs may be provided at one or more of locations L1 to L37, and such SOAs may be controlled to amplitude modulate the optical signals supplied thereto, such as modulate the optical signals to carry low frequency tones <1 MHz. Such tones may be needed for detecting relative power of the different optical paths to provide inputs to control circuitry that control the SOAs, phase adjustors, or other optical elements.

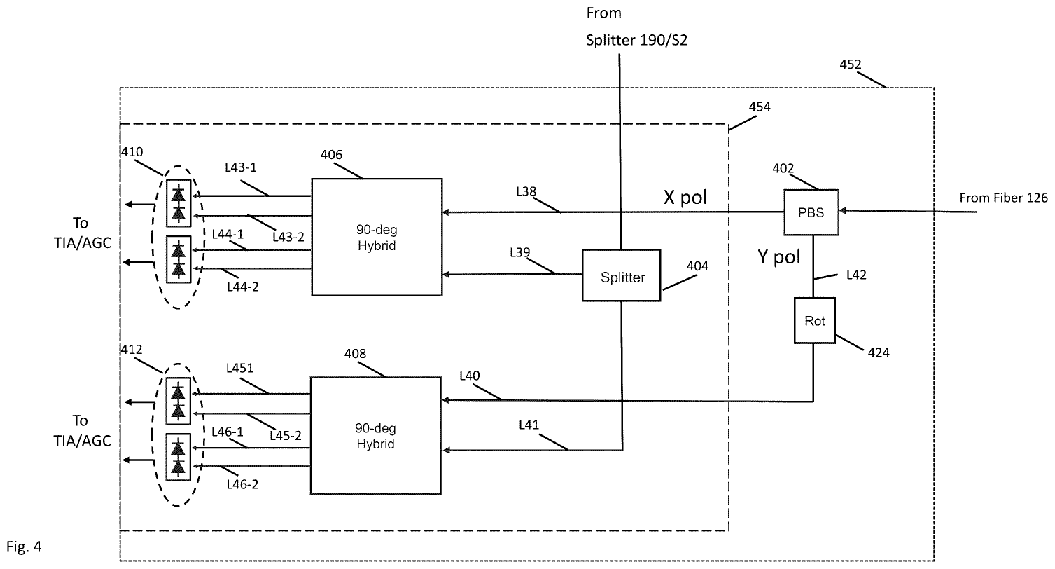

FIG. 4 shows an example of receiver 118 in greater detail. Receiver 118 has a first optical input which receives an incoming modulated optical signal from fiber 126 and a local oscillator signal from port P2 of splitter 190 or from side S2 of laser 110 (see FIG. 2). The local oscillator (LO) signal is supplied to a splitter having a first output that provides a first power split portion to 90 degree optical hybrid 406 and a second power split portion of the LO signal to 90 degree optical hybrid 408. The incoming modulated optical signal from fiber 126 is provided to polarization beam splitter 402, which provides a Y polarization component of the incoming signal to a rotator 424 and a X polarization component of the incoming signal to optical hybrid 406. Rotator 424 rotates the polarization of the received Y polarization component to the X polarization, and such rotated component is provided to 90 degree optical hybrid 408. Optical hybrid 406 mixes the received first LO portion with the output of the PBS 402 to provide a first plurality of mixing products, which are supplied to photodiode circuit 410. Also, optical hybrid 408 mixes the received second LO portion with the rotated output of rotator 424 to provide a second plurality of mixing products, which are supplied to photodiode circuit 412. The electrical outputs of photodiode circuits 410 and 412 are provided to circuitry including transimpedance amplifiers (TIAs) and automatic gain control (AGC) circuits for further processing.

As further shown in FIG. 4, various SOA locations (L38 to L46) are labeled in FIG. 4. SOAs may be provided at one or more of these locations to facilitate power balancing of the TE (e.g., one or more of locations L38, L39 L43-1, L43-2, L44-1, and L44-2 to adjust power of the X polarization optical power) Y polarization signals (e.g., one or more of locations L40, L41, L42, L45-1, L45-2, L46-1, and L46-2). Alternatively, as noted above, SOAs may be provided at one or more locations L38, L40, and L42 to boost X polarization and Y polarization components of the incoming optical signal, and, therefore, improve the SNR of such components. It is noted that, in the event, SOAs are provided at the outputs of the optical hybrid circuits 406 and 408, additional circuitry may be required to process the signals output from such SOAs.

Moreover, although each of the components shown in FIG. 4 may be provided on substrate 101, some of these components may be provided on one substrate while others are provided on another substrate. For example, each of the components shown in FIG. 1 may be provided on substrate 452, which may be separate from substrate 101. Alternatively, PBS 402 and rotator 424 may be provided on substrate 454, which may be separate from both substrate 452 as well as substrate 101. In a further example, PBS 402 and rotator 424 are realized with free space optical elements, such as lenses and free-standing optical elements. Accordingly, consistent with the present disclosure, polarization beam splitting and polarization rotation may be realized with elements or devices integrated onto a one or more substrate. Moreover, such polarization beam splitting and polarization rotation may be realized with optical elements that are not integrated onto a substrate, such as free space optical elements, such as lenses, and free-standing optical elements.

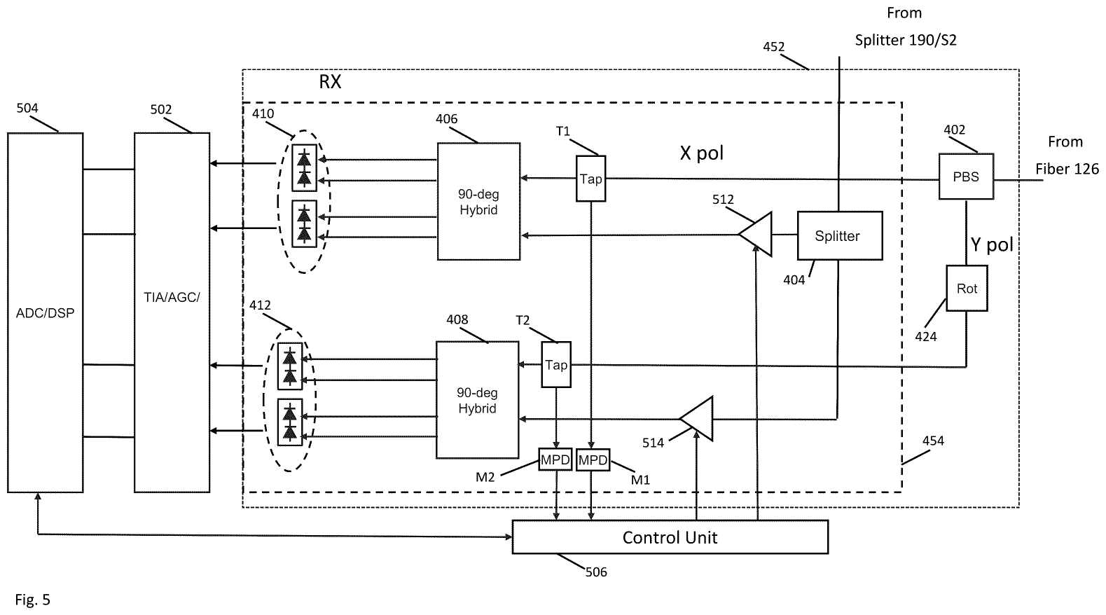

FIG. 5 shows a receiver similar to that shown in FIG. 4. In FIG. 5, however, circuit block 502 including TIA, AGC, and analog-to-digital conversion circuits is shown that receives the electrical outputs of the photodiode circuits and provides outputs to a digital signal processor 504. In addition, a first optical tap (T1) is provided at an input to optical hybrid 406 and a second optical tap (T2) is provided at an input to optical hybrid 408. Tap T1 provides a portion of the X polarization component to a first monitor photodiode M1, and tap T2 provides a portion of the rotated Y polarization component to a second monitor photodiode M2. The outputs of the M1 and M2 are provided to control circuit 506, which also exchanges related data with the TIA circuitry included in block 502 and DSP 504. In one example, control circuit 506 provides outputs, which may be a voltage and/or current for adjusting the gain of SOAs 512 and 514 for optimal performance based on an SNR or ROSNR (receiver optical SNR), measured or determined by input optical signal power, and by how much the amplified signal from the AGC is filling the ADC. Consistent with a further aspect of the present disclosure, an additional SOA may be provided to amplify the optical output portion that is fed to monitor photodiode M2.

FIGS. 6-9 illustrate examples of SOAs which may be employed in the embodiments described above.

FIG. 6 illustrates a longitudinal cross-sectional view of an SOA consistent with the present disclosure. The SOA includes a substrate and a metal contact to the substrate if the substrate is n-type. An n-type cladding layer is provided on the substrate and a p-type cladding layer is provided on the n-type cladding layer with an optical core layer provided therebetween. A p-type layer is provided on the p-type cladding layer and three contact electrodes, C1, C2, and C3 are provided on the p-type layer. In addition, electrical isolation regions are provided between contact C1 and contact C2, and between contact C2 and contact C3. Contact C1 associated with an input section beneath contact C1 provides sufficient current to minimize the noise figure of the SOA. The middle section of the SOA is provided beneath contact C2. Current and/or voltages supplied to contact C2 are used to control a variable gain of the SOA. Current and/or voltages applied to contact C3 are used to adjust the output signal level and minimize gain compression distortions. In one example, if the signal level is too high compared to a saturation signal level, the signal level is adjusted to avoid distortions in the signal.

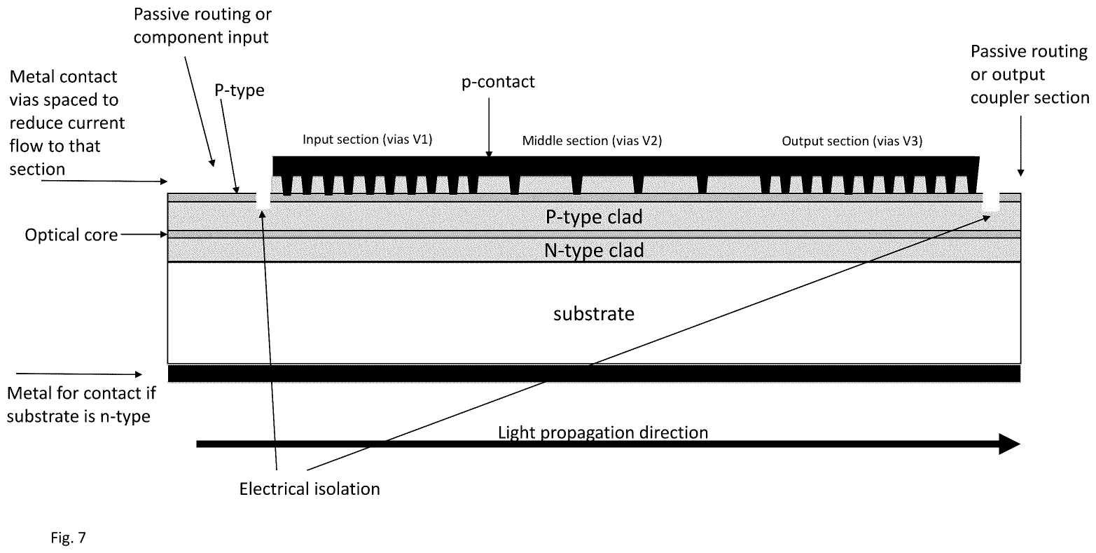

FIG. 7 illustrates an additional example of an SOA consistent with the present disclosure. The example shown in FIG. 7 is similar to the example shown in FIG. 6. In FIG. 7, however, rather than separate contact electrodes C1 to C3, a single conductive contact is provided. The following description of FIG. 7 provides an example of how different densities of vias and therefore current density scaling may be used. In the input section of the SOA, a relatively large number of contact vias (V1) is provided to supply sufficient current to minimize the noise figure of the SOA. In the middle section, fewer conductive vias are provided than in the input section. In the middle section of the SOA, as in the example shown in FIG. 7, current is provided by the conductive vias (V2) therein to provide less current density to this section of the SOA. In the output section, a large number of conductive vias (compared to the middle section) are provided for better linearity at high output power levels. As noted above, if the signal level is too high compared to a saturation signal level, the SOA current or the input SOA power level is adjusted to avoid excessive distortions in the modulated signal. Unmodulated light coming directly from the laser may be amplified in the saturation regime.

The example shown in FIG. 7 may be advantageous in that one control contact is required to adjust the current supplied to the SOA, thereby simplifying control of the SOA while making efficient use of the supplied current. In some examples, one control contact is preferred if desired performance can be achieved.

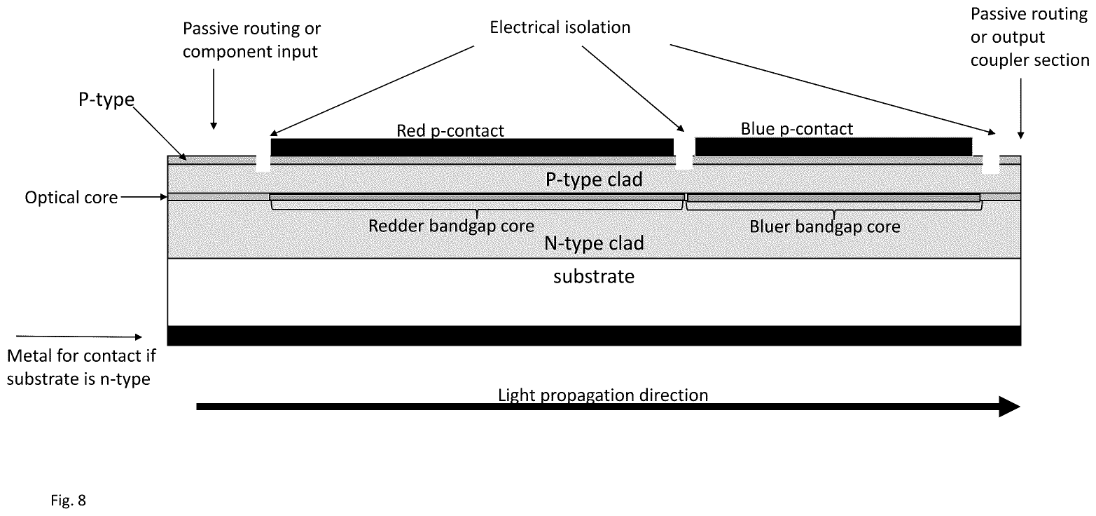

FIG. 8 shows an SOA which is also similar to that shown in FIG. 6. In FIG. 8, however, the optical core layer includes a first “redder bandgap core” region having a first relatively narrow bandgap, and a second “bluer bandgap core” region having a second relatively wide bandgap. A first “red” p-contact is provided above the redder bandgap core region, and a second “blue” p-contact is provided above bluer bandgap core region. Accordingly, by supplying appropriate currents to the red and blue p-contacts the gain can be tailored for different wavelengths included in the signal to be amplified. In one example, although the optical signal input to the optical amplifier may nominally be at a single wavelength, the optical signal may include additional wavelengths, which may be spectrally close to the nominal wavelength, but are above and below the nominal wavelength. The red and blue contacts noted above allow for independent control of gain imparted to wavelengths above (red) and below (blue) the nominal wavelength. The direction of light propagation is shown for reference. In some circuit designs, it may be more advantageous to have the blue section precede the red section for best overall performance, accounting for output power, TOSNR, minimizing power dissipation, and other needs.

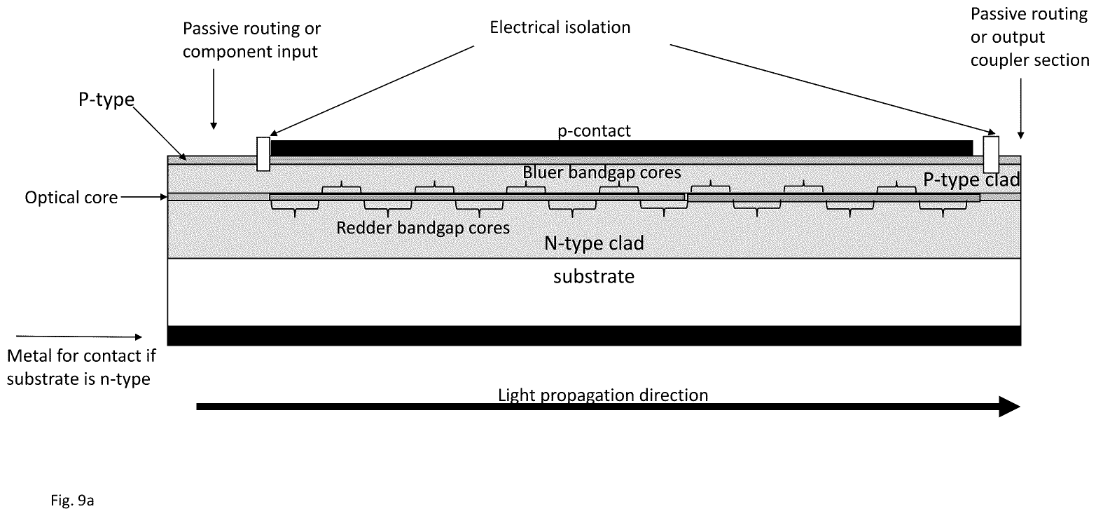

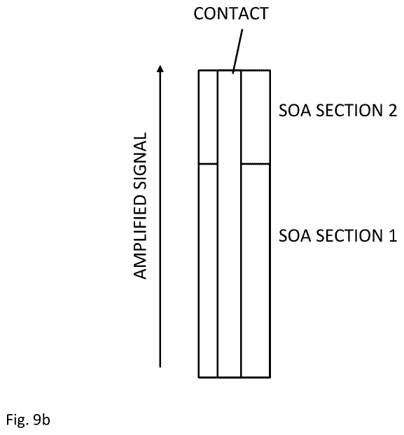

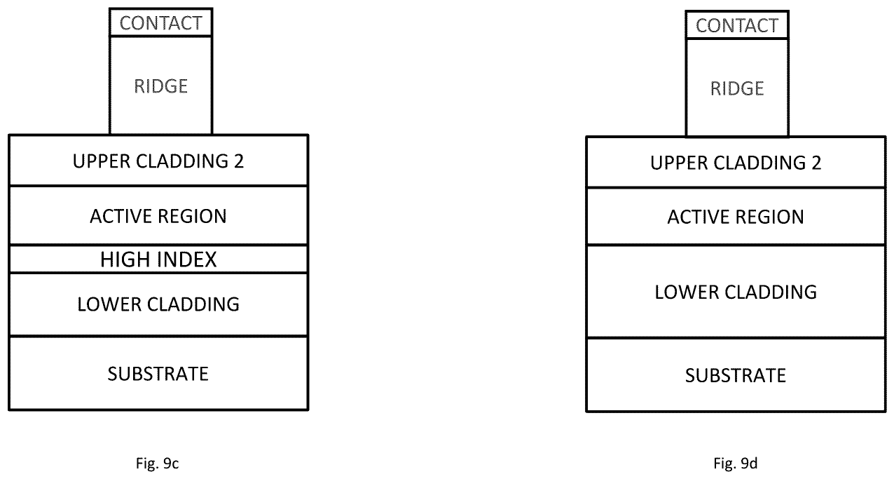

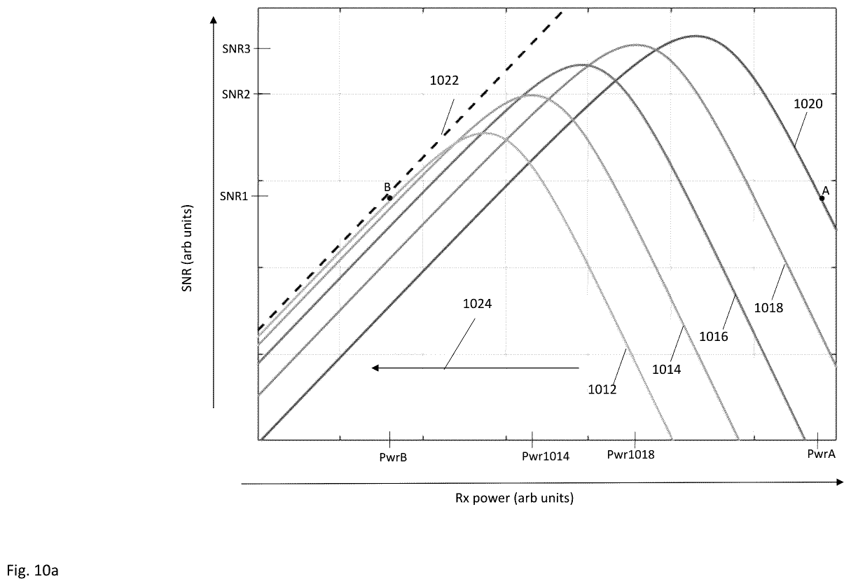

The example shown in FIG. 9a is similar to that shown in FIG. 8. In FIG. 9a, however, a plurality of red core regions and a plurality of blue core regions are provided, whereby the red and blue core regions are interspersed amongst each other. Put another way, a blue core region is provided between pairs of red core regions. As further shown in FIG. 9 a p-contact is provided above the pluralities of red and blue core regions. Here, since the red and blue core regions are interspersed, the gain experienced by the “red” and “blue” wavelengths of the modulated optical signal is spread out or rendered more uniform. Accordingly, multiple contacts are not necessary.

As noted above with respect to FIG. 5, control circuit or unit 506 may be used to adjust or control the current supplied to SOA 512 and 514, and thus the gains of these SOAs. Consistent with a further aspect of the present disclosure, if the received optical signal power level is relatively high, as measured by monitor photodiodes M1 and M2, the current supplied by control circuit 506 to SOAs 512 and 514, which amplify respective portions of the LO signal, is reduced. As a result, the gain imparted to the LO signal portions is correspondingly reduced. On the other hand, if the received optical signal power level is relatively low, as measured by the monitor photodiodes M1 and M2, the current supplied by control circuit 506 to SOAs 512 and 514 is increased, so that the gain imparted to the LO signal portions is increased. As a result, greater sensitivity and improved dynamic range may be achieved.

FIG. 9b shows a plan view of another example of a multi-section SOA consistent with an aspect of the present disclosure. Here, the SOA includes Sections 1 and 2, whereby the optical signal passing through the SOA first enters Section 1 and is then supplied from Section 1 to Section 2, as indicated by the arrow shown in FIG. 9b. One contact layer or electrode is provided that extends over and electrically contacts both Sections 1 and 2.

FIG. 9c shows a cross-sectional view of Section 1 of the SOA. As shown in FIG. 9c, a lower cladding layer is provided on substrate 101, and a high index layer, having a refractive index greater than the lower cladding layer is provided within the lower cladding layer. An active region layer is provided above the high index layer, and an upper cladding layer is provided on the active region layer. Next, a ridge layer or waveguide having a width that is narrower than the upper cladding layer is provided on the upper cladding layer, and a contact or conductive layer is provided on the ridge layer. Here, the high index layer is provided close to the active region to pull the guided optical mode center lower than the center of the action region, to reduce the active region confinement and gain per unit length, which is beneficial, in particular, if the input signals to the SOA are relatively strong and less signal distortion and higher saturation output power are desired.

FIG. 9d shows a cross-sectional view of Section 2 of the SOA illustrated in FIG. 9b. As shown in FIG. 9d, Section 2 is similar to Section 1. In FIG. 9d, however, the high index layer is omitted. Here, the active region confinement is increased, as well as gain per unit length. Accordingly, weak signals experience more gain, thereby benefiting from more amplification for a given drive current. For an example, the FIG. 9d configuration is used when signal distortion is less of a concern than power dissipation. The layers in these FIGS. 9c and 9d are appropriately doped to form diodes. The SOAs described above in connection with in FIGS. 1-8, 9a, and 9b-9d are exemplary. SOAs consistent with the present disclosure may be fabricated in accordance with a ridge waveguide process to provide the SOA structures shown in FIGS. 9c and 9d. Alternatively, a buried heterostructure process may be employed. Other SOA device structures may be employed.

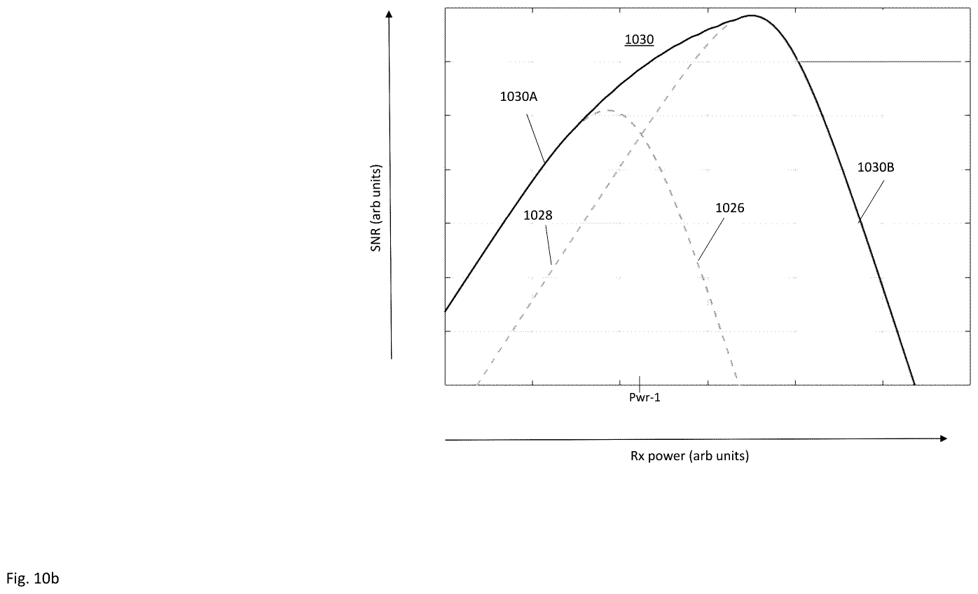

FIG. 10a illustrates a series of curves, 1012, 1014, 1016, 1018, and 1020, each being a plot of signal-to-noise ratio (SNR) at the receiver vs received optical signal power (Rx power) for a respective fixed SOA gain for amplifying the LO signal. The fixed gain associated with each curve increases in a direction indicated by arrow 1024, such that curve 1020 is associated with an SOA having the lowest fixed gain and curve 1012 is associated with an SOA having the highest fixed gain. Accordingly, for example, curve 1018 is associated with an SOA having a fixed gain that is greater than the fixed gain associated with curve 1020 but less than the fixed gain associated with curve 1016. In addition, the fixed gain associated with curve 1014 is greater than the fixed gain associated with curve 1016, but less than the fixed gain associated with curve 1012.

As further shown in FIG. 10a, each of curves 1012, 1014, 1016, 1018, and 1020 follows a similar trend. Namely, as gain increases, SNR increases for higher Rx powers. However, such SNR increases are limited by shot noise, as indicated by curve 1022. Accordingly, each of curves, 1012, 1014, 1016, 1018, and 1020 has a corresponding peak or maximum SNR at a particular Rx power. For example, at an Rx power of Pwr1018, curve 1018 has an associated peak signal-to-noise ratio of SNR3, and, at an Rx power of Pwr1014, curve 1014 has an associated peak signal-to-noise ratio of SNR 2. Moreover, at an Rx power of PwrA, curve 1020 has the highest signal-noise-ratio (SNR1 at point A) of the remaining curves, even though the fixed gain associated with curve 1020 is the lowest relative to the fixed gains associated with the remaining curves. At an Rx power of PwrB, however, curve 1012 has the highest SNR (see point B, SNR1). Thus, for a given Rx power, there is a maximum SNR based on gain. Put another way, the maximum SNR that can be achieved is gain dependent, such that a lower gain may provide a maximum SNR at higher Rx powers and a higher gain may provide the maximum SNR at lower Rx powers.

FIG. 10b illustrates curves 1026 and 1028 associated with an SOA having a fixed higher gain (curve 1026) and a fixed lower gain (1028). As further shown in FIG. 10b, curve 1026 has a higher SNR than curve 1028 at Rx powers less than Pwr−1, and curve 1028 has a higher SNR than curve 1026, for example, at Rx powers greater than Pwr−1. Accordingly, as further shown in FIG. 10b, by varying or controlling the SOA gain based on input power, an optimal or maximum SNR may be achieved. Curve 1030 is associated with an SOA having a gain that depends on Rx power to provide such maximum input power-dependent SNR. That is, the gain associated with curve 1026 yields the greatest SNR for input powers (Rx power) less than Pwr−1. Accordingly, portion 1030A of curve 1030 tracks curve 1026 for such input powers and to thereby provide maximum SNR for such input powers. On the other hand, for input powers greater than Pwr−1, portion 1030B of curve 1030 generally track curve 1028 to provide the maximum SNR for input powers greater than Pwr−1.

Thus, consistent with a further aspect of the present disclosure, however, a control circuit, such as control circuit 506 in FIG. 5, may be provided to adjust the gain of the SOA, e.g., SOAs 512 and 514, to thereby adjustably amplify the LO signal based on the Rx power. For example, as noted above with respect to FIG. 10b, for lower Rx power, the SOA gain is controlled to be relatively high, whereas, for higher Rx power, the SOA gain is controlled to be relatively low, such that an optimal or maximum SNR is achieved subject to the Shot Noise for a particular Rx power.

As a result, improved sensitivity can be achieved for low Rx powers compared to a fixed high gain SOA. In addition, an improved or wider dynamic range can be obtained compared to the dynamic range associated with a fixed gain SOA implementation. Moreover, the optimal SOA gain and corresponding maximum SNR combination can be realized with minimum performance penalties.

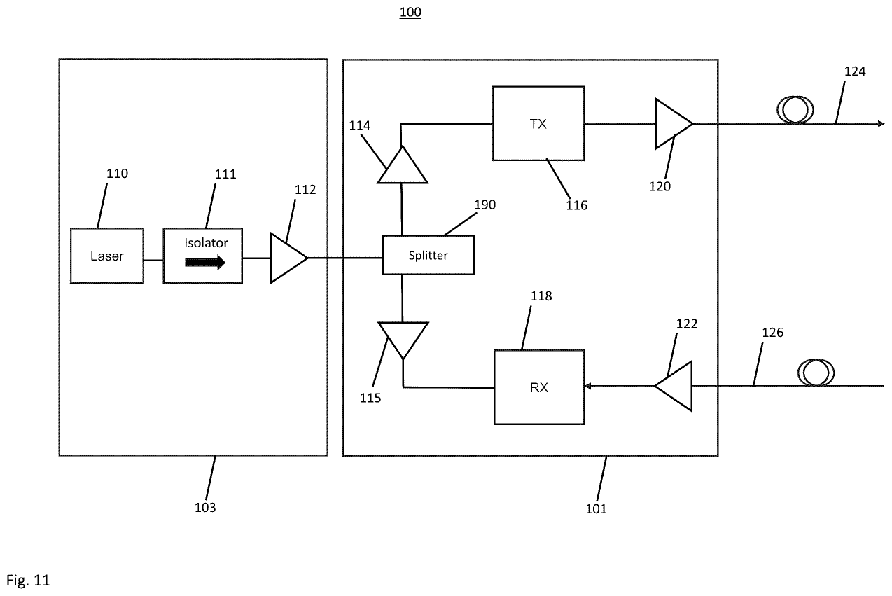

FIG. 11 illustrates another example of transceiver 100 consistent with a further aspect of the present disclosure. The example shown in FIG. 11 is similar to that shown in FIG. 1. In FIG. 11, however, transceiver 100 includes two substrates, substrates 101 and substrate 103. Substrate 103 may include a Group III-V semiconductor material, such as indium phosphide (InP), and substrate 101 in each of the examples disclosed herein includes similarly includes a Group III-V semiconductor, such as InP. Substrate 101 has a PIC provided thereon including one or more of SOAs 114, 115, 120, and 122, as well as the transmitter (116) and receiver (118) portions noted above. Second substrate 103 has laser 110 provided thereon and optional SOA 112. An optical isolator 111 may also be optically coupled between laser 110 and SOA 112 to prevent back reflections into laser 110. An optical fiber or free space optics including a lens, for example, may be provided to optically couple light output from SOA 112 or directly from laser 110, if SOA 112 is absent, to an input to splitter 190 on substrate 101.

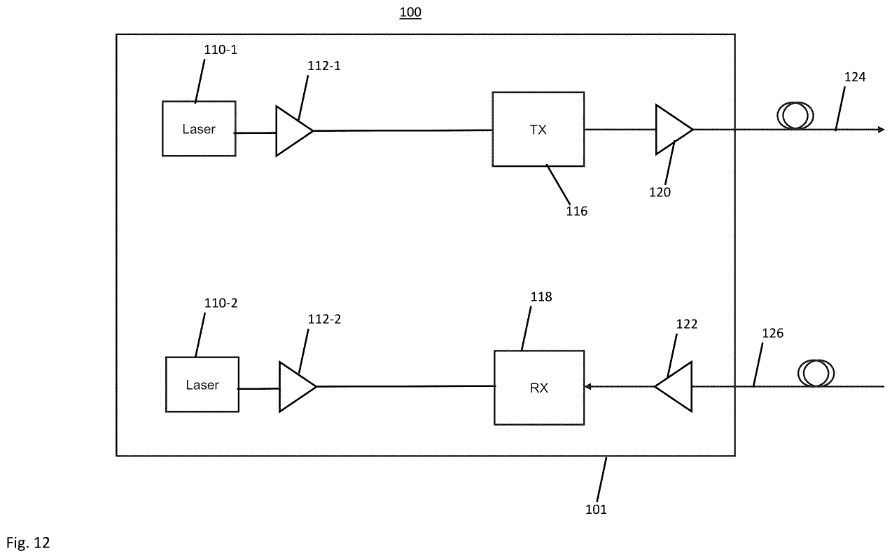

FIG. 12 illustrates a further embodiment consistent with the present disclosure. The example of transceiver 100 shown in FIG. 12 is similar to that shown in FIG. 1. In FIG. 12, however, splitter 190, as well as SOAs 114 and 115 are omitted. Further, in FIG. 12, two lasers 110-1 and 110-2 are provided, each of which supplies light to SOAs, 112-1 and 112-2, each of which being optionally provided. Each of lasers 110-1 and 110-2 shown in FIG. 12 is provided on substrate 101, along with SOAs 112-1, transmitter (116) and receiver (118) portions described above, and optional SOAs 120 and 122. In another example, lasers 110-1 and 110-2 may be provided on a separate substrate, such as substrate 103.

Other embodiments will be apparent to those skilled in the art from consideration of the specification. For example, in each instance where an SOA is described above, a variable optical attenuator may be employed instead. Such VOA may be realized by appropriately biasing the SOA so that the SOA gain or output power is reduced relative to peak output power and effectively induces a loss relative to peak power. The SOA can be biased such that it becomes absorptive and imparts a net loss to the optical signal applied thereto, as opposed to imparting a gain to such signal. The amount of gain or loss can be adjusted or controlled based on the level of the bias. Accordingly, the VOA, according to a further aspect of the present disclosure, has a variable gain. In one example, such variable gain is based on monitor photodiodes, as described above. Consistent with another aspect, the VOA may instead be a device similar to an SOA but with sufficiently different bandgap, insertion loss or modal overlap that operation as an SOA would be undesirable or impossible. Alternatively, the VOA may be a Mach-Zehnder VOA, which may have a relatively large range. Such Mach-Zehnder VOA may be provided after the MZMs noted above, and/or at the receiver input.

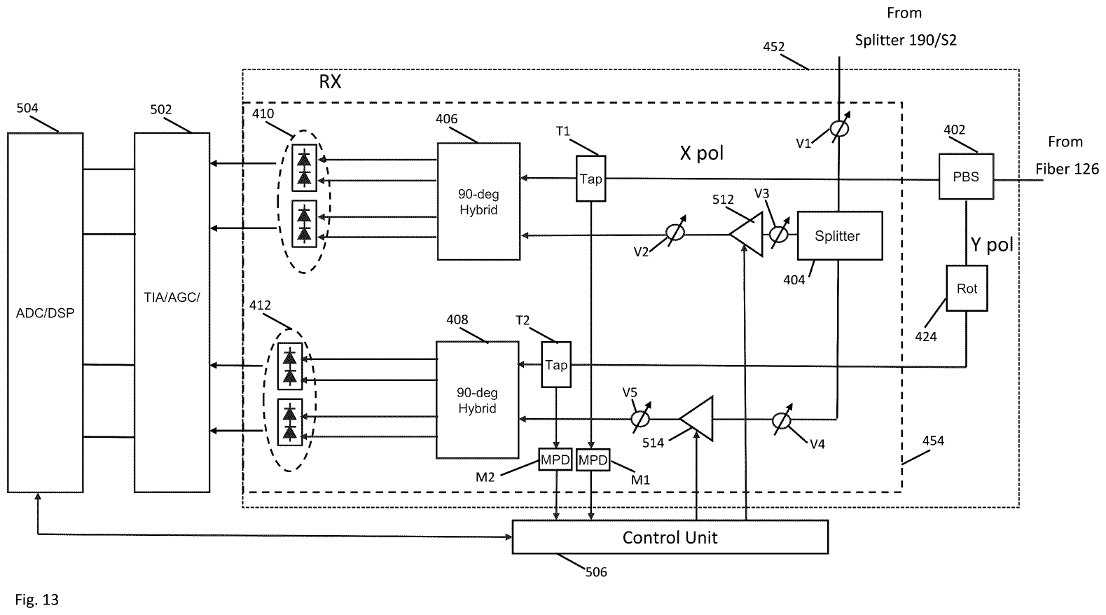

FIG. 13 is similar to FIG. 5 but shows examples of locations in the RX where one or more of the VOAs described above may be provided. In one example, a VOA (VOA1) may be provided before or at the input of splitter 404. In a further example, VOAs V3 and V4 may be provided at the outputs of splitter 404. If SOAs 512 and 514 are provided, VOAs V3 and V4 may be provided at the respective inputs of such SOAs. In addition or alternatively, VOAs V2 and V5 may be provided at the outputs of SOAs 512 and 514, respectively. It is noted that each of the VOAs noted above may be included in the RX in the locations identified in FIG. 13 or fewer such VOAs may be provided depending on system requirements.

In further examples, the present disclosure contemplates direct detection of intensity modulated optical signals, as opposed to coherent detection as noted above. In that case, the optical hybrid circuits and local oscillator light (and associated laser, such as laser 110-2 in FIG. 12) may be omitted and optical signals may be directly input from optical fiber 126, with or without amplification.

It is intended that the specification and examples be considered as exemplary only, with a true scope and spirit of the invention being indicated by the following claims.

What is claimed is:

1. A photonic integrated circuit, comprising:
a substrate;
a laser provided on the substrate;
a modulator provided on the substrate;
an optical path provided on the substrate, wherein light output from the laser propagates along the optical path, the optical path including the laser and the modulator, such that the modulator is operable to modulate the light output from the laser to provide a modulated optical signal; and
an optical amplifier provided on the substrate, said at least one optical amplifier being included in the optical path, wherein the optical amplifier, the laser, and the modulator are monolithically integrated on the substrate, the optical amplifier being operable to amplify the modulated optical signal.

2. A photonic integrated circuit in accordance with claim 1, wherein the optical amplifier is coupled to an input to the modulator.

3. A photonic integrated circuit in accordance with claim 1, wherein the substrate includes indium phosphide.

4. A photonic integrated circuit, comprising:
a substrate;
a Mach-Zehnder modulator provided on the substrate, the Mach-Zehnder modulator including:
a splitter having an input and first and second outputs,
a combiner having an output and first and second inputs, a semiconductor optical amplifier optically coupled between the first output of the splitter and the first input of the combiner.

5. A photonic integrated circuit in accordance with claim 4, wherein the semiconductor optical amplifier is a first semiconductor optical amplifier, the photonic integrated circuit further including:
a second semiconductor optical amplifier optically coupled between the second output of the splitter and the second input of the combiner.

6. A photonic integrated circuit in accordance with claim 5, further including a laser, wherein the first and second semiconductor optical amplifiers are operable to adjust a phase of the light output from the laser.

7. A photonic integrated circuit in accordance with 5, wherein the first and second semiconductor optical amplifiers are further operable to adjust an amplitude of the light output from the laser.

8. A photonic integrated circuit in accordance with 4, wherein the first and second semiconductor optical amplifiers are further operable to adjust an amplitude of the light output from the laser.

9. An apparatus, comprising:
a photonic integrated circuit, including:
a laser operable to provide an optical signal,
a splitter operable to receive the optical signal, and provide a first portion of the optical signal at a first output of the splitter and a second portion of the optical signal at a second output of the splitter,
a first Mach-Zehnder modulator operable to receive the first portion of the optical signal and supply a first modulated optical signal, and
a second Mach-Zehnder modulator operable to receive the second portion of the optical signal and supply a second modulated optical signal;
a polarization rotator operable to rotate a polarization of the first modulated optical signal;
a polarization beam combiner operable having first and second inputs operable to receive the first and second modulated optical signals, respectively, the polarization beam combiner be further operable to combine the polarization rotated first modulated optical signal and the second modulated optical signal onto an optical waveguide; and
a semiconductor optical amplifier provided in the photonic integrated circuit,
wherein the first output of the splitter, the first Mach-Zehnder modulator, and the first input of the polarization beam combiner define a first optical path, and the second output of the splitter, the second Mach-Zehnder modulator, and the second input of the polarization beam combiner define a second optical path, the semiconductor optical amplifier being optically coupled to the first optical path.

10. An apparatus in accordance with claim 9, wherein the semiconductor optical amplifier is provided at an output of the polarization beam combiner.

11. An apparatus in accordance with claim 10, wherein the semiconductor optical amplifier is polarization insensitive.

12. An apparatus in accordance with claim 9, wherein the semiconductor optical amplifier is a first semiconductor optical amplifier, the photonic integrated circuit further including a second semiconductor optical amplifier being optically coupled to the second optical path.

13. An apparatus in accordance with 9, wherein the semiconductor optical amplifier is optically coupled to the first optical path such that the semiconductor optical amplifier receives a modulated optical signal output from the first Mach-Zehnder modulator.

14. A photonic integrated circuit in accordance with claim 9, wherein the semiconductor optical amplifier is a first semiconductor optical amplifier, the photonic integrated circuit further including a second semiconductor optical amplifier being optically coupled to the second optical path, such that the first semiconductor optical amplifier is optically coupled to the first optical path and receives a first modulated optical signal output from the first Mach-Zehnder modulator, and the second semiconductor optical amplifier is optically coupled to the second optical path and receives a second modulated optical signal output from the second Mach-Zehnder modulator.

15. An apparatus in accordance with claim 9, further including a substrate, wherein the laser, the splitter, first and second Mach-Zehnder modulators, and the semiconductor optical amplifier are monolithically integrated on the substrate.

16. An apparatus in accordance with claim 9, wherein the semiconductor optical amplifier is provided at an input to the splitter.

17. An apparatus in accordance with claim 5, wherein the first semiconductor optical amplifier provides a first variable gain and the second semiconductor optical amplifier provides a second variable gain.

18. An apparatus in accordance with claim 1, wherein the semiconductor optical amplifier provides a variable gain.

19. An apparatus in accordance with claim 9, wherein the semiconductor optical amplifier provides a variable gain.

20. An apparatus in accordance with claim 12, wherein the first semiconductor optical amplifier and the second semiconductor optical amplifier are biased to provide first and second gains, respectively.
